(19) United States
(12) Patent Application Publication
(10) Pub. No.: US 2010/0177484 A1
(43) Pub. Date: Jul. 15, 2010

(54) HEAT SINK

(75) Inventors: XIAO-FENG MA, Shenzhen City (CN); ZHENG-HENG SUN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/400,747

(22) Filed: Mar. 9, 2009

(30) Foreign Application Priority Data
Jan. 12, 2009 (CN) 200910300146.7

(51) Int. Cl. H05K 7/20

(52) U.S. Cl. 361/720

(57) ABSTRACT

A heat sink for cooling an electronic element of a circuit board includes a dissipating part configured for dissipating heat, and a mounting part configured for mounting the heat sink to the circuit board. The mounting part extends from the dissipating part integrally.

### BACKGROUND

1. Technical Field

The disclosure relates to heat sinks.

2. Description of Related Art

In a computer, electronic elements of the mother board, such as the central processing unit and the south bridge, need to be cooled. Heat sinks are most widely used for cooling the electronic elements. Generally, a heat sink includes a dissipating part for dissipating heat, and a mounting part for mounting the heat sink to the motherboard. The dissipating part mainly includes a plurality of fins, and the mounting part mainly includes a clip. A clip generally includes a lot of parts, such as a clipping ring, a pressing member, and a plurality of screws, etc. However it is inconvenient to combine so many parts together to assemble a heat sink.

### BRIEF DESCRIPTION OF THE DRAWINGS

FIG. 1 is an exploded, isometric view of a first exemplary embodiment of a heat sink and a circuit board.

FIG. 2 is an assembled, lateral view of FIG. 1.

FIG. 3 is similar to FIG. 2, showing the heat sink being detached.

FIG. 4 is an exploded, isometric view of a second exemplary embodiment of a heat sink and a circuit board.

FIG. 5 is an assembled view of FIG. 4, but viewed from another aspect.

### DETAILED DESCRIPTION

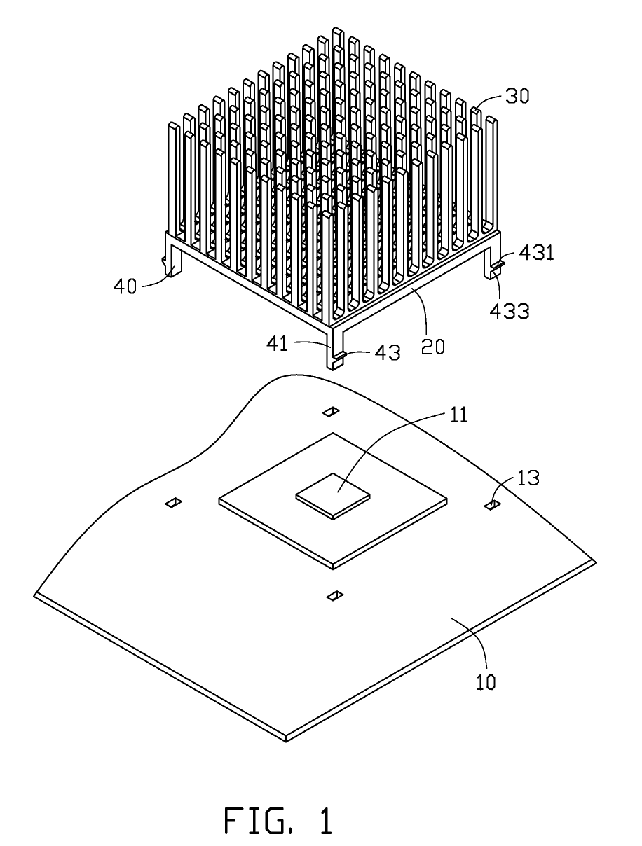

Referring to FIG. 1, a first exemplary embodiment of a heat sink is used for cooling an electronic element 11 of a circuit board 10, and includes a dissipating part, and a mounting part. The circuit board 10 may be a motherboard, and the electronic element 11 may be a central processing unit or a south bridge. A plurality of mounting holes 13 is defined in the circuit board 10 around the electronic element 11. For the purpose of describing the embodiment of the heat sink, the number of the mounting holes 13 is four, and the mounting holes 13 are square holes.

The dissipating part of the heat sink includes a square base 20, and a plurality of fins 30 extending upward from a surface of the base 20. The base 20 is configured to contact directly with the electronic element 11 and conduct heat from the electronic element 11 to the fins 30.

The mounting part of the heat sink includes a plurality of pegs 40 extending downward from the base 20 corresponding to the mounting holes 13 of the circuit board 10. In the present embodiment, the number of the pegs 40 is four, and the pegs 40 extend from the four corner portions of the base 20, respectively, in a direction opposite to the extending direction of the fins 30. Each peg 40 includes a bar 41 extending perpendicularly from the base 20, and a barb 43 extending from a side of the bar 41. The barb 43 includes a horizontal blocking surface 431 facing upward, and a slanting or arc guiding surface 433 facing downward.

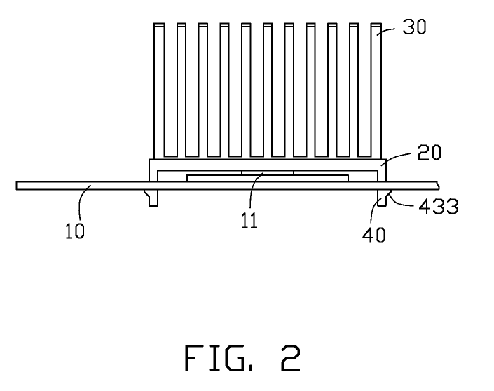

Referring also to FIG. 2, in installing the heat sink, the pegs 40 of the heat sink are inserted in the corresponding mounting holes 13 of the circuit board 10. The guiding surface 433 of each barb 43 engages a portion bounding the corresponding mounting hole 13, and guides the corresponding barb 43 to slide into the corresponding mounting hole 13 and leads the corresponding bar 41 to be elastically bent inward. When the barbs 43 pass through the corresponding mounting holes 13, the bars 41 restore and the blocking surfaces 431 of the barbs 43 abut against the bottom surface of the circuit board 10. Thus the bottom of the base 20 firmly abuts against the electronic element 11.

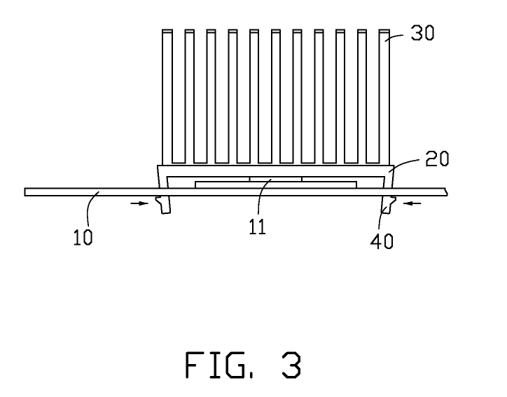

Referring also to FIG. 3, in disassembly, the barbs 43 are pushed inward to elastically bend the bar 41 so that the blocking surfaces 431 of the barbs 43 disengage from the bottom of the circuit board 10. The heat sink is drawn upward to make the barbs 43 to detach from the circuit board 10.

The heat sink of the present disclosure is integratively formed, so that a lot of parts, such as clipping rings, pressing members and screws, are not necessary. Thus, the process of assembly of the heat sink can be omitted, installing the heat sink becomes easier, and the cost for the heat sink is reduced.

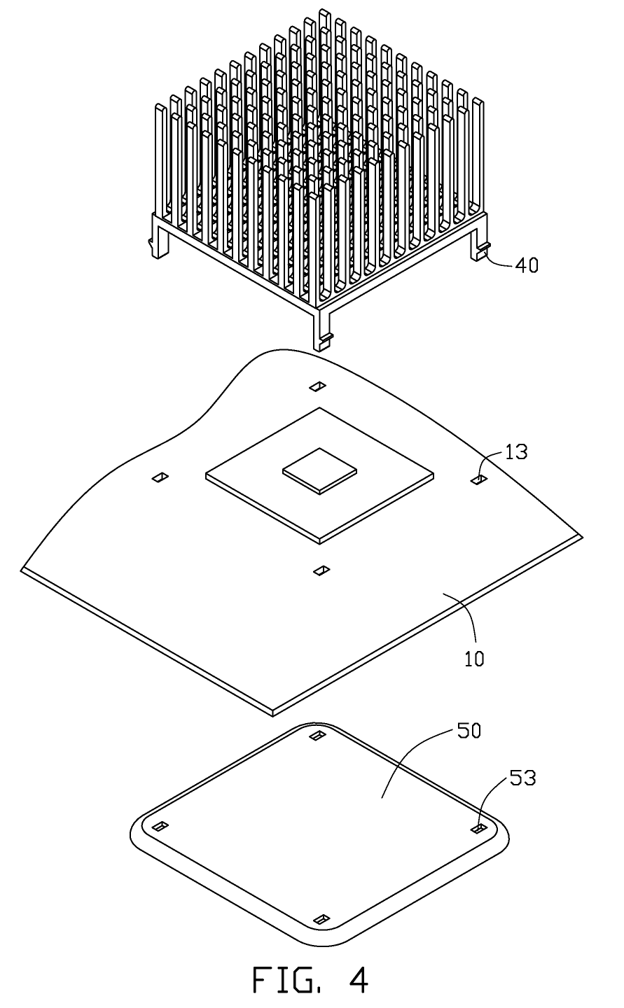

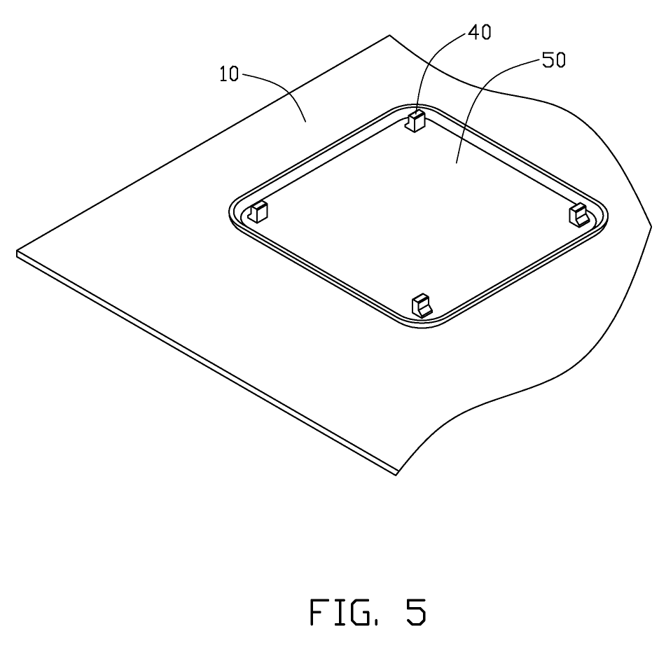

Referring to FIGS. 4 and 5, a second exemplary embodiment of a heat sink is shown. The difference between the first and second exemplary embodiments is that the heat sink in the second exemplary embodiment further includes a reinforcing plate 50. The reinforcing plate 50 defines a plurality of through holes 53 corresponding to the mounting holes 13 of the circuit board 10. In use, the pegs 40 are inserted in the corresponding mounting holes 13 firstly, and then the reinforcing plate 50 is mounted to bottom of the board 10 via the barbs 43 of the pegs 40 being inserted through the corresponding through holes 53 of the reinforcing plate 50 and clipping the reinforcing plate 50. The reinforcing plate 50 abuts against the bottom of the circuit board 10 so that the circuit board 10 is sandwiched between the reinforcing plate 50 and the dissipating part, wherein the reinforcing plate 50 is used for preventing the circuit board 10 from being warped by too much force being used to engage the pegs 40.

It is to be understood, however, that even though numerous characteristics and advantages of the disclosure have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink for cooling an electronic element of a circuit board with a plurality of mounting holes defined therein, comprising:
a dissipating part configured for dissipating heat; and
a mounting part configured for mounting the heat sink to the circuit board;
wherein the mounting part extends from the dissipating part integrally.

2. The heat sink of claim 1, wherein the dissipating part comprises a base, and a plurality of fins extending from the base along a first direction, the base is configured to contact with the electronic element and conduct heat from the electronic element to the fins.

3. The heat sink of claim 2, wherein the mounting part comprises a plurality of pegs extending from the base along a second direction opposite to the first direction, the pegs are capable of being inserted into the mounting holes of the circuit board respectively to engage with the circuit board.

4. The heat sink of claim 3, wherein the base is square, the number of the pegs is four and the pegs are extending from four corner portions of the base.

5. The heat sink of claim 3, wherein each peg comprises a bar extending perpendicularly from the base, and a barb extending from a side of the bar, the barb is capable of being inserted into the corresponding mounting hole of the circuit board and abutting against the bottom of the circuit board.

6. The heat sink of claim 5, wherein each barb comprises a blocking surface perpendicular to the bar and configured for abutting against the bottom of the circuit board.

7. The heat sink of claim 6, wherein each barb comprises a slanting guiding surface slantingly extending from the bar and configured for guiding the barb to slide into the corresponding mounting hole of the circuit board.

8. The heat sink of claim 6, wherein each barb comprises an arc guiding surface and configured for guiding the barb to slide into the corresponding mounting hole of the circuit board.

9. The heat sink of claim 3, further comprising a reinforcing plate for preventing the circuit board from being warped, wherein the reinforcing plate defines a plurality of through holes corresponding to the plurality of mounting holes of the circuit board, upon a condition that the pegs being inserted through the mounting holes of the circuit board, the reinforcing plate is capable of being mounted to the circuit board via the pegs being inserted through the corresponding through holes of the reinforcing plate and clipping the reinforcing plate.
